(19) United States
(12) Patent Application Publication
(10) Pub. No.: US 2025/0087506 A1
(43) Pub. Date: Mar. 13, 2025

(54) TARGETED GAS DELIVERY VIA SIDE GAS INJECTION

(71) Applicant: Applied Materials, Inc., Santa Clara, CA (US)

(72) Inventors: Tobin KAUFMAN-OSBORN, Sunnyvale, CA (US); Christopher S. OLSEN, Fremont, CA (US)

(21) Appl. No.: 18/463,457

(22) Filed: Sep. 8, 2023

(51) Int. Cl. H01L 21/67; H01J 37/32

(52) U.S. Cl. CPC H01L 21/67115; H01J 37/32357; H01J 37/3244; H01L 21/67017

(57) ABSTRACT

The present disclosure provides an apparatus and methods for processing a substrate. The apparatus includes a chamber body defining a processing volume. The apparatus further includes a base ring and a substrate support disposed in the processing volume. A gas source assembly is in fluid communication with an inlet of the chamber body. An exhaust assembly is in fluid communication with an outlet of the chamber body. A side injection assembly is in fluid communication with a first gas source, in which the side injection assembly is coupled to the base ring of the chamber body. The side injection assembly includes an elongated structure that extends towards the processing volume and a first side inject actuator coupled to the elongated structure and configured to control a first inject angle of the elongated structure relative to the base ring

### BACKGROUND

### Field

The present disclosure relates generally to semiconductor processing and, more specifically, to a reactor with improved gas flow distribution.

### Description of the Related Art

Semiconductor substrates are processed for a wide variety of applications, including the fabrication of integrated devices and microdevices. One method of processing substrates includes growing an oxide layer on an upper surface of the substrate within a processing chamber. The oxide layer may be deposited by exposing the substrate to oxygen and hydrogen gases while heating the substrate with a radiant heat source. The oxygen radicals strike the surface of the substrate to form a layer, for example a silicon dioxide layer, on a silicon substrate.

Current processing chambers used for radical oxygen growth have limited growth control due to lack of control of the combustion process at the edge of a substrate support and/or substrate, resulting in poor processing uniformity. For example, low processing chamber pressure requirements for radial oxygen growth and current gas inlet designs result in gas reaching the substrate at a high velocity, preventing the gas from being adequately heated at the edge of the substrate. Additionally, oxygen radicals generated from combustion quickly recombine to create a short life cycle for the oxygen radicals. As such, such chambers have limited growth control, commonly resulting in greater growth at the center of the substrate and insufficient growth at the edges of the substrate.

Therefore, there is a need for improved processing techniques that provide greater control for more uniform film growth throughout the substrate.

### SUMMARY

The present disclosure provides an apparatus for processing a substrate. The apparatus includes a chamber body defining a processing volume. The apparatus further includes a base ring and a substrate support disposed in the processing volume. A gas source assembly is in fluid communication with an inlet of the chamber body. An exhaust assembly is in fluid communication with an outlet of the chamber body. A side injection assembly is in fluid communication with a first gas source, in which the side injection assembly is coupled to the base ring of the chamber body. The side injection assembly includes an elongated structure that extends towards the processing volume and a first side inject actuator coupled to the elongated structure and configured to control a first inject angle of the elongated structure relative to the base ring.

The present disclosure also provides an apparatus for thermal processing a substrate. The apparatus includes a base ring having sidewalls defining a processing volume. The base ring includes an inlet and an outlet formed through the sidewalls, in which the inlet and the outlet are formed on opposite sides of the base ring. A substrate support is disposed in the processing volume and has a substrate supporting surface. A heat source is positioned to provide thermal energy to the processing volume. An exhaust assembly is coupled to the outlet of the base ring. A side injection assembly is in fluid communication with a first gas source. The side injection assembly is coupled to the base ring and includes an elongated structure that extends towards the processing volume and a first side inject actuator coupled to the elongated structure. The first side inject actuator is configured to control a first inject angle of the elongated structure relative to the base ring.

The present disclosure also provides a method of processing a substrate. The method includes positioning a substrate in a processing volume of a process chamber. The process chamber has an inlet and an outlet formed on opposite sides of the process chamber. A first gas flow is provided from the inlet to the outlet. The processing volume is pumped using an exhaust assembly coupled to the outlet. A second gas flow is provided from a side injection assembly coupled to a base ring of the chamber body in a direction that is tangential to an edge of the substrate. An inject angle of the second gas flow is adjusted using a side inject actuator.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1A is a schematic, cross-sectional representation of a thermal processing chamber that may be used to practice implementations of the present disclosure.

FIG. 1B is a schematic cross-sectional top view of the thermal processing chamber according to one implementation of the present disclosure.

FIG. 2 is a graph of an oxide thickness of a substrate oxidized using a side injection assembly as a function of a distance from a center of the substrate.

FIG. 3 is a graph of an oxide non-uniformity % of a substrate coated with a side injection assembly as a function of a total side inject flow.

FIG. 4 is a graph of an oxide thickness of a substrate coated with a side injection assembly as a function of a distance from a center of the substrate.

FIG. 5 is an oxide density of a substrate coated with a side injection assembly as a function of a distance from a center of the substrate.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

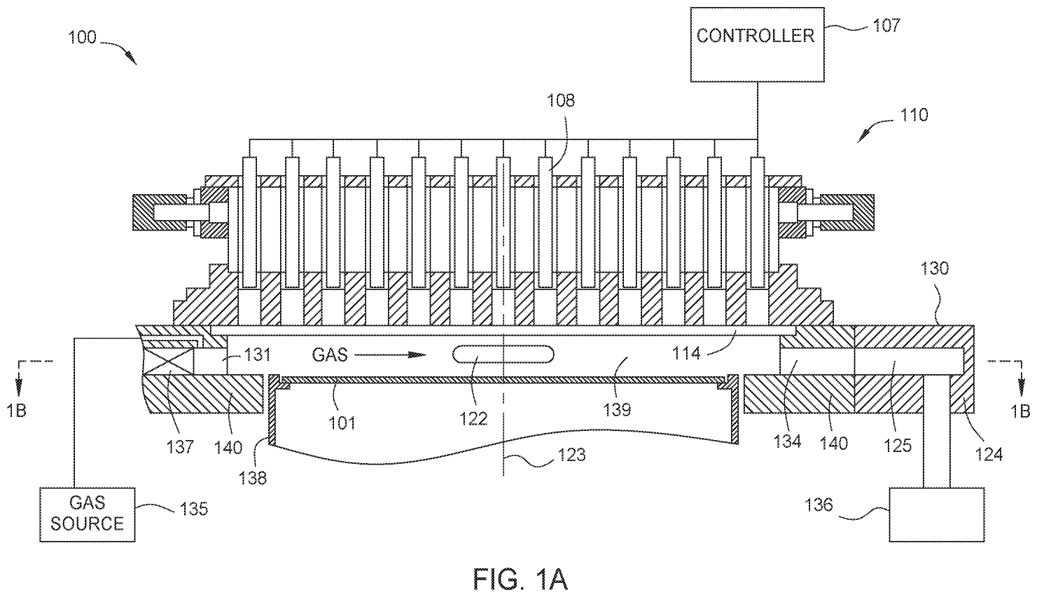

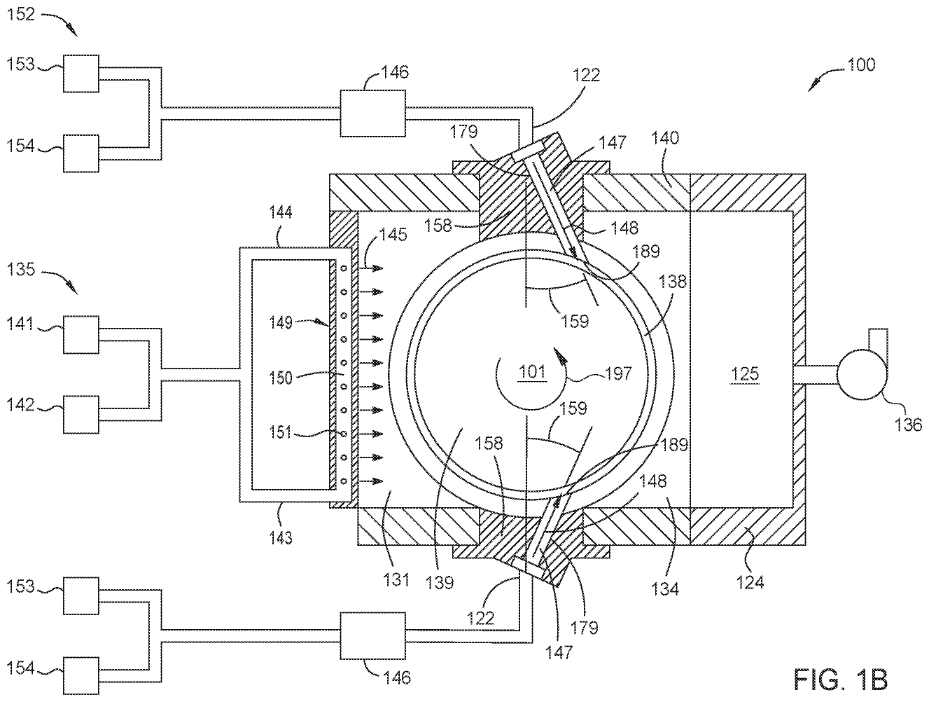

FIG. 1A is a schematic, cross-sectional representation of a thermal processing chamber 100 that may be used to practice implementations of the present disclosure. The thermal processing chamber 100 generally includes a lamp assembly 110, a chamber assembly 130 defining a processing volume 139, and a substrate support 138 disposed in the processing volume 139. The thermal processing chamber 100 is capable of providing a controlled thermal cycle that heats a substrate 101 for processes such as, for example, thermal annealing, thermal cleaning, thermal chemical vapor deposition, thermal oxidation and thermal nitridation, etc.

The lamp assembly 110 may be positioned relatively above the substrate support 138 to supply heat to the processing volume 139 via a quartz window 114. The quartz window 114 is disposed between the substrate 101 and the lamp assembly 110. The lamp assembly 110 may additionally or alternatively be disposed relatively below the substrate support 138 in some implementations. It is noted that the term “above” or “below” as used in this disclosure are not referring to absolute directions. The lamp assembly 110 is configured to house a heating source 108, such as a plurality of tungsten-halogen lamps for providing a tailored infrared heating means to a substrate 101 disposed on the substrate support 138. The plurality of tungsten-halogen lamps may be disposed in a hexagonal arrangement. The heating source 108 may be connected to a controller 107 which may control the energy level of the heating source 108 to achieve a uniform or tailored heating profile to the substrate 101. In one example, the heating source 108 is capable of rapidly heating the substrate 101 at a rate of from about 50° C./s to about 280° C./s.

The substrate 101 may be heated to a temperature ranging from about 550 degrees Celsius to about less than 1,200 degrees Celsius. The heating source 108 may provide zoned heating (temperature tuning) of the substrate 101. Temperature tuning may be performed to change the temperature of the substrate 101 at certain locations while not affecting the rest of the substrate temperature. In one implementation, the center of the substrate 101 is heated to a temperature that is 10 degrees Celsius to about 50 degrees Celsius higher than the temperature of the edge of the substrate 101.

A silt valve 137 may be disposed on the base ring 140 for a robot to transfer the substrate 101 into and out of the processing volume 139. The substrate 101 may be placed on the substrate support 138, which may be configured to move vertically and to rotate about a central axis 123. A gas inlet 131 may be disposed over the base ring 140 and connected to a gas source 135 to provide one or more processing gases to the processing volume 139. A gas outlet 134, formed on an opposite side of the base ring 140 from the gas inlet 131, is adapted to an exhaust assembly 124 which is in fluid communication with a pump system 136. The exhaust assembly 124 defines an exhaust volume 125, which is in fluid communication with the processing volume 139 via the gas outlet 134.

In one implementation, one or more side ports 122 may be formed over the base ring 140 between the gas inlet 131 and the gas outlet 134. The side port 122, the gas inlet 131, and the gas outlet 134 may be disposed at substantially the same level or elevation. That is, the side port 122, the gas inlet 131, and the gas outlet 134 may be intersected by a common plane. As will be discussed in more detail below, the side ports 122 is connected to a side gas source configured to improve gas distribution uniformity near edge areas of the substrate 101.

FIG. 1B is a schematic cross-sectional top view of the thermal processing chamber 100 of FIG. 1A according to one implementation of the present disclosure. As shown in FIG. 1B, the gas inlet 131 and gas outlet 134 are disposed on opposite sides of the processing volume 139. Both of the gas inlet 131 and the gas outlet 134 may have a linear or azimuthal width which is approximately equal to a diameter of the substrate support 138.

In one implementation, the gas source 135 may comprise multiple gas sources, for example a first gas source 141 and a second gas source 142, each configured to provide a processing gas. During operation, processing gases from the first gas source 141 and the second gas source 142 may mix together prior to entering an injection cartridge 149 disposed at the inlet 131. Alternatively, the processing gas from the second gas source 142 may be introduced to the injection cartridge 149 after the processing gas from the first gas source 141 has been introduced to the injection cartridge 149. The first gas source 141 may provide a gas that has a lower thermal conductivity and thus controls the combustion reaction.

In one implementation, the first gas source 141 provides an oxygen containing gas, such as oxygen gas, and the second gas source 142 provides a hydrogen containing gas, such as hydrogen gas. The second gas source 142 may also provide oxygen, nitrogen, or a mixture thereof. The gas from the first gas source 141 may be heated to a first temperature prior to entering the injection cartridge 149. The first temperature may be about 300° C. to about 650° C., for example about 550° C. The gas from the second gas source 142 may be provided to the injection cartridge 149 at room temperature. Alternatively, both the gas from the first gas source 141 and the gas from the second gas source 142 may be provided to the injection cartridge 149 at room temperature.

In one implementation, the injection cartridge 149 has an elongated channel 150 formed therein and two inlets 143, 144 formed on opposite ends of the elongated channel 150. A plurality of injecting holes 151 are evenly distributed along the elongated channel 150 and are configured to inject a main gas flow 145 towards the processing volume 139. The two-inlet design of the cartridge 149 improves uniformity among the gas flow from each of the plurality of injecting holes 151. The main gas flow 145 may include 30 to 50 percent hydrogen gas by volume and 50 to 70 percent oxygen gas by volume, and have a flow rate ranging from about 20 standard liters per minute (slm) to about 50 slm. The flow rate is based on the substrate 101 having a 300 mm diameter, which leads to a flow rate ranging from about 0.028 slm/cm² to about 0.071 slm/cm².

Under the vacuum force from the pump system 136, the main gas flow 145 is directed from the gas inlet 131 towards the gas outlet 134. In one implementation, the exhaust volume 125 of the exhaust assembly 124 is configured to extend the processing volume 139 to reduce the geometry influence of the chamber structure to the main gas flow 145. Particularly, the exhaust volume 125 is configured to extend the processing volume 139 along the direction of the main gas flow 145. The exhaust volume 125 may improve the uniformity of the main gas flow 145 across the processing volume 139 from the inlet 131 to the outlet 134. The pump system 136 may be also used to control the pressure of the processing volume 139. In one implementation, the pressure inside the processing volume ranges from about 1 Torr to about 19 Torr, such as between about 5 Torr to about 15 Torr.

In one implementation, a side injection assembly 147 is coupled to the base ring 140 so that a gas is flowed along a side gas flow 148 to the processing volume 139 via the side port 122. The side injection assembly 147, the injection cartridge 149, and the exhaust assembly 124 are angularly offset at about 90° with respect to each other. For example, the side injection assembly 147 may be located on a side of the base ring 140 between the injection cartridge 149 and the exhaust assembly 124, with the injection cartridge 149 and the exhaust assembly 124 disposed at opposing ends of the base ring 140. The side injection assembly 147, the injection cartridge 149, and the exhaust assembly 124 may be intersected by a common plane. In one implementation, the side injection assembly 147, the injection cartridge 149, and the exhaust assembly 124 are aligned to each other and disposed at substantially the same level. In one implementation, the inner surface 179 of the side injection assembly 147 is configured so that it extends along a direction 189 that is substantially tangential to the edge of the substrate 101, or substantially tangential to the edge of the substrate supporting surface of the substrate support 138.

The side injection assembly 147 is in fluid communication with a gas source 152 via a flow adjusting device 146 configured to control a flow rate of the side gas flow 148. The gas source 152 may include one or more gas sources. In one implementation, the gas source 152 is a single gas source that provides a hydrogen containing gas, such as hydrogen gas. In one implementation, the gas source 152 is a single gas source that provides an oxygen containing gas, such as oxygen gas. In one implementation, the gas source 152 is a single gas source that provides a mixed gas of a hydrogen containing gas, such as hydrogen gas, and an oxygen containing gas, such as oxygen gas. In another implementation, the gas source 152 is, or coupled to a remote radical source that generate radicals to the side port 122.

In one example, the gas source 152 is a remote plasma source (RPS) that produces hydrogen radicals to the side port 122. For a process that heats the substrate with lamps and injects hydrogen and oxygen into the processing chamber 100 from the slit valve 137, the side injection assembly 147 may be configured to inject the hydrogen radicals into the processing volume 139. The hydrogen radicals introduced from the side injection assembly 147 improve the reaction rate along the edge of the substrate 101, resulting in an oxide layer having improved thickness uniformity. The side gas flow 148 may have a flow rate ranging from about 5 slm to about 25 slm. For a substrate with a 300 mm diameter, the flow rate ranges from about 0.007 slm/cm² to about 0.035 slm/cm².

In some alternative implementations, the gas source 152 may contain multiple gas sources, for example a first gas source 153, and a second gas source 154, each configured to provide a processing gas. The first gas source 153 and the second gas source 154 may be the same or different in chemical composition. The processing gases from the first gas source 153 and the second gas source 154 may be mixed together prior to entering the flow adjusting device 146. In one implementation, the side gas flow 148 may be independently controlled relative to the main gas flow 145 and may include the same gas components as the main gas flow 145. The composition and the flow rate of the side gas flow 148 are important factors in forming an oxide layer having improved thickness uniformity.

In the implementation shown in FIG. 1B, the side injection assembly 147 may include an elongated structure that has a variable diameter, where the elongated structure extends towards the processing volume 139. The elongated structure may be an elongated channel with any desired shape in cross-section, such as rectangular, square, round, polygonal, hexagonal, or any other suitable shape. The side injection assembly 147 may include a flow actuator for adjusting the diameter of the side injection assembly 147. The flow actuator may adjust the diameter of the side injection assembly 147 to be greater than the diameter of the side port 122. Alternatively, the flow actuator may adjust the diameter of the side injection assembly 147 to be less than the diameter of the side port 122. Without being bound by theory, varying the diameter of the side injection assembly 147 may allow for decoupling the gas velocity and direction of the target such that the area of the substrate that is most in need of additional flux may be targeted by adjusting a gas velocity and/or an angle of the flow actuator. This variable diameter allows for a change in flow and/or velocity of the gas and/or radicals to be injected, increasing control of the oxidation.

In some implementations, the elongated structure may be oriented at an angle so that the side gas flow 148, either gas or radicals, is flowing in a direction that is proximate the tangent of the substrate 101 or the substrate supporting surface of the substrate support 138. The term “proximate” described herein refers to a distance between the side gas flow 148 and the edge of the substrate 101. The distance may be within about 20 mm of the edge of the substrate 101, for example about 1 mm to about 10 mm. That is, a flow path of the gas or radicals (i.e., the side gas flow 148) and a tangent line to the substrate 101 or the substrate supporting surface of the substrate support 138 parallel to the flow path of the gas or radicals are about 1 mm to about 10 mm apart. Flowing of the gas or radicals in a direction proximate the tangent line of the substrate or tangential to the outer edge of the substrate, has been observed to increase the thickness profile of the oxide, the oxide uniformity, and density of the oxide at the edges of the substrate.

The side injection assembly 147 may include a side inject actuator 158. The side inject actuator 158 may adjust an inject angle 159 of side injection assembly 147. The inject angle may be an angle from about 0.01 degrees to about 90 degrees, relative to a normal line of the base ring 140. In some embodiments, a first angle of a first side injection assembly 158-1 is controlled independently of a second angle of a second side injection assembly 158-2. For example, a first side injection assembly 158-1 may have a first inject angle that is different than a second side injection assembly 158-2 having a second inject angle. Alternatively, a first side injection assembly may have an inject angle that is the same as a second side injection assembly.

In addition, since the substrate 101 is rotated along counter clockwise direction 197, the gas velocity of the majority of the side gas flow 148 coming in from the side injection assembly 147 may be slowed down by adjusting the diameter of the side injection assembly, as described above. For example, the gas velocity may be adjusted by a factor of 5 or greater (e.g., a factor of 10), which results in greater growth at the edge of the substrate 101. The gas velocity of the side gas flow 148 may be adjusted by adjusting a flow rate of the side gas flow 148. The gas velocity of the side gas flow 148 may be adjusted by adjusting a diameter of the side injection assembly 147. The gas velocity of the side gas flow 148 may be adjusted by adjusting a rotation speed of the substrate 101. The gas velocity of the side gas flow 148 may be adjusted by adjusting the inject angle of the side injection assembly 147. Without being bound by theory the gas velocity can be adjusted so that the side gas flow 148 does not travel too fast and prevent the side gas flow 148 from being adequately reacted with the main gas flow 145, or too slow such that the rotation of the substrate 101 may drag the side gas flow 148 away from the edge of the substrate 101 without being adequately reacted with the main gas flow 145. As a result, the thickness profile, the oxide uniformity, and density at the edges of the substrate are improved.

The side injection assembly 147 may be made of any suitable material such as quartz, quartz lined, ceramic, ceramic coated, aluminum, stainless steel, steel, or the like.

Although FIG. 1B show the substrate 101 is rotating along counter clockwise direction, the substrate 101 may be rotated along clockwise direction and also benefit from the side gas flow 148.

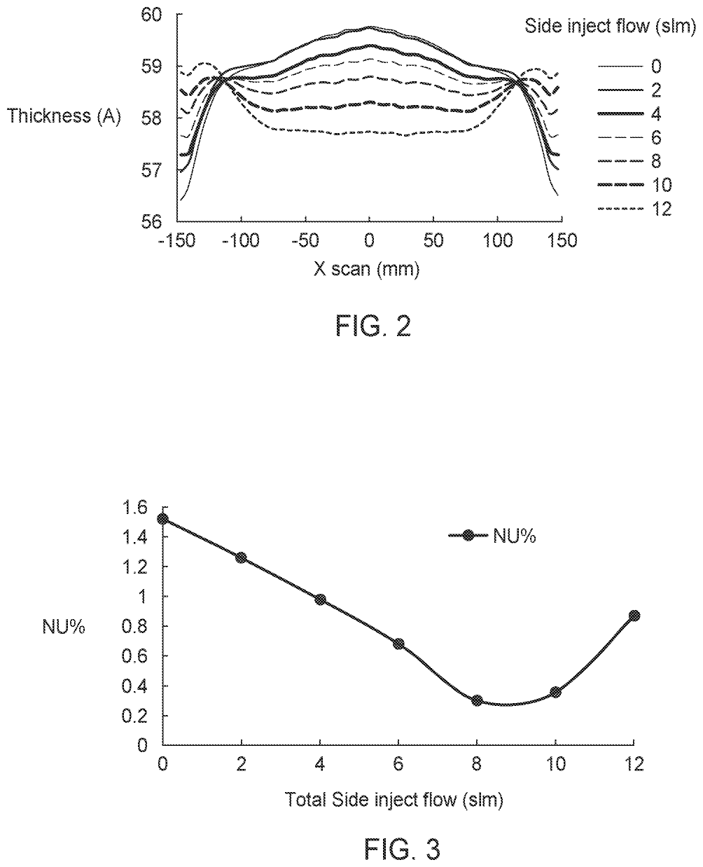

FIG. 2 illustrates an oxide thickness of a substrate oxidized using a side injection assembly as a function of a distance from a center of the substrate, in which the side injection assembly flowed 0 slm, 2 slm, 4 slm, 6 slm, 8 slm, 10 slm, or 12 slm of a 33% mixture of H₂ gas and inert gas and a processing chamber temperature of 1,000 degrees Celsius. As shown, the oxide thickness became more uniform as the flow of the reactive gas from the side injection assembly was increased.

FIG. 3 shows an oxide non-uniformity % of a substrate coated with a side injection assembly as a function of a total side inject flow, in which the side injection assembly flowed 0 slm, 2 slm, 4 slm, 6 slm, 8 slm, 10 slm, or 12 slm of a reactive gas, e.g., oxygen, hydrogen, or a combination thereof. As shown, the non-uniformity % decreased with increasing flow of the side injection assembly, in which 8 slm performed had the lowest non-uniformity % of the various flow rates. The non-uniformity % increased at the 12 slm flow rate.

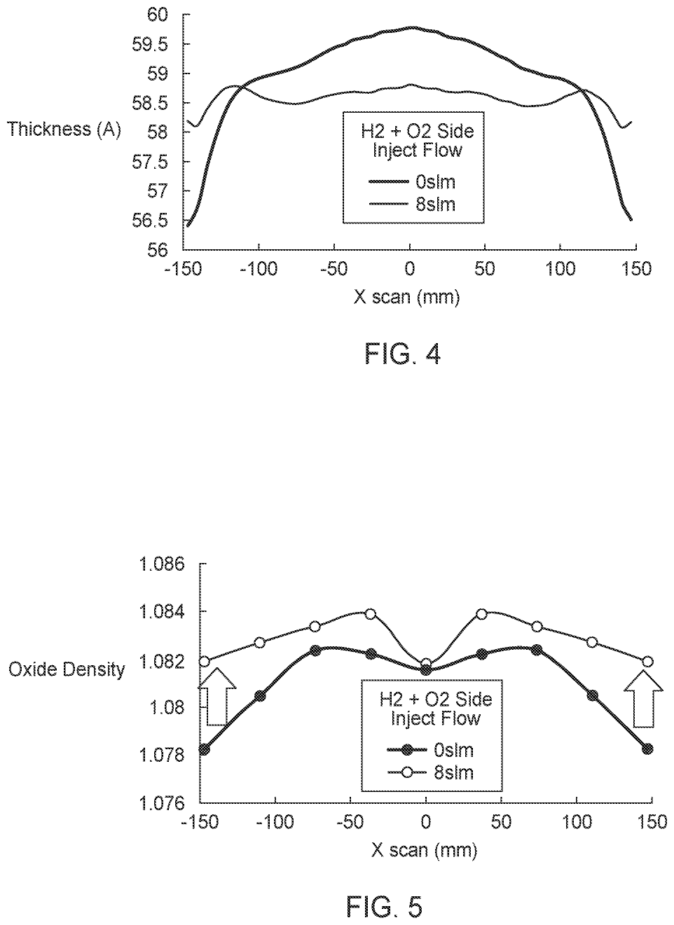

FIG. 4 shows an oxide thickness of a substrate coated with a side injection assembly as a function of a distance from a center of the substrate, in which the side injection assembly flowed 0 slm and 8 slm of a mixture of H₂ and O₂ reactive gas mixture. As shown, the oxide thickness of the substrate exposed to an 8 slm flow rate was more uniform compared to the 0 slm flow rate.

FIG. 5 shows an oxide density of a substrate coated with a side injection assembly as a function of a distance from a center of the substrate, in which the side injection assembly flowed 0 slm and 8 slm of a mixture of H₂ and O₂ reactive gas mixture. As shown, the oxide density of the substrate exposed to an 8 slm flow rate was increased at the edges of the substrate, in which the oxide density was more uniform and provided less oxide density variation along the length of the substrate.

Benefits of the present disclosure include the use of an improved side injection assembly in a processing chamber to direct gas or radicals towards the edge of the substrate to control growth uniformity throughout the substrate, e.g., from the center to the edge. The side injection assembly may include a modifiable diameter gas inlet configured to point to the gas exhaust side (e.g., pump system) of the processing chamber. The side injection assembly may have a variable angle allowing for the decoupling of gas velocity and direction to target the area of the substrate most in need of additional flux (e.g., an edge of the substrate), while maintaining the ability to modify gas flow to customize impact.

While the foregoing is directed to implementations of the present disclosure, other and further implementations of the disclosure may be devised without departing from the basic scope thereof, and the scope thereof is determined by the claims that follow.

What is claimed is:

1. An apparatus for processing a substrate, comprising:
a chamber body defining a processing volume, the chamber body comprising a base ring;
a substrate support disposed in the processing volume;
a gas source assembly in fluid communication with an inlet of the chamber body;
an exhaust assembly in fluid communication with an outlet of the chamber body; and
a side injection assembly in fluid communication with a first gas source, the side injection assembly coupled to the base ring of the chamber body, the side injection assembly comprising:
an elongated structure that extends towards the processing volume; and
a first side inject actuator coupled to the elongated structure and configured to control a first inject angle of the elongated structure relative to the base ring.

2. The apparatus of claim 1, wherein the elongated structure comprises a variable diameter.

3. The apparatus of claim 2, further comprising a flow actuator for adjusting the variable diameter.

4. The apparatus of claim 1, wherein the first side inject actuator controls the first inject angle of the elongated structure from an angle of about 0.01 degrees to about 90 degrees relative to the base ring.

5. The apparatus of claim 1, further comprising a second side inject actuator configured to control a second inject angle relative to the base ring.

6. The apparatus of claim 5, wherein the first inject angle is different than the second inject angle.

7. The apparatus of claim 5, wherein the first inject angle is the same as the second inject angle.

8. The apparatus of claim 1, wherein the side injection assembly is further in fluid communication with a second gas source, wherein the first gas source and the second gas source include different chemical compositions.

9. The apparatus of claim 8, wherein the first gas source comprises an oxygen containing gas, and the second gas sources comprises a hydrogen containing gas.

10. An apparatus for thermal processing a substrate, comprising:
a base ring having sidewalls defining a processing volume, the base ring comprising an inlet and an outlet formed through the sidewalls, wherein the inlet and the outlet are formed on opposite sides of the base ring;
a substrate support disposed in the processing volume, wherein the substrate support has a substrate supporting surface;
a heat source positioned to provide thermal energy to the processing volume;
an exhaust assembly coupled to the outlet of the base ring; and
a side injection assembly in fluid communication with a first gas source, the side injection assembly coupled to the base ring, wherein the side injection assembly comprises:
an elongated structure that extends towards the processing volume; and
a first side inject actuator coupled to the elongated structure and configured to control a first inject angle of the elongated structure relative to the base ring.

11. The apparatus of claim 10, wherein the elongated structure comprises a variable diameter.

12. The apparatus of claim 10, wherein the first side inject actuator controls the first inject angle of the elongated structure from about 0.01 degrees to about 90 degrees relative to the base ring.

13. The apparatus of claim 12, further comprising a second side inject actuator configured to control a second angle relative to the base ring.

14. The apparatus of claim 13, wherein the first inject angle is different than the second inject angle.

15. The apparatus of claim 13, wherein the first inject angle is the same as the second inject angle.

16. The apparatus of claim 10, wherein the side injection assembly is further in fluid communication with a second gas source, wherein the first gas source and the second gas source are different in chemical composition.

17. A method of processing a substrate, comprising:
positioning a substrate in a processing volume of a process chamber, wherein the process chamber has an inlet and an outlet formed on opposite sides of the process chamber;
providing a first gas flow from the inlet to the outlet;
pumping the processing volume using an exhaust assembly coupled to the outlet;
providing a second gas flow from a side injection assembly coupled to a base ring of the chamber body in a direction that is tangential to an edge of the substrate; and
adjusting an inject angle of the second gas flow using a side inject actuator.

18. The method of claim 17, further comprising rotating the substrate continuously about a center of the substrate.

19. The method of claim 17, wherein adjusting the angle comprises adjusting an elongated structure from about 0.01 degrees to about 90 degrees.

20. The method of claim 17, further comprising heating the substrate using a heat source disposed above or below the processing volume.
